(19) United States
(12) Patent Application Publication
(10) Pub. No.: US 2020/0277185 A1
(43) Pub. Date: Sep. 3, 2020

(54) METHODS FOR IMPROVING LOADING RATIO OF HYDROGEN GAS

(71) Applicant: IH IP HOLDINGS LIMITED, St. Helie (JE)

(72) Inventors: Darren R. Burgess, Charlotte, NC (US); Michael Raymond Greenwald, Indian Trail, NC (US); Brent W. Barbee, Stanfield, NC (US)

(21) Appl. No.: 16/070,630

(22) PCT Filed: Jan. 23, 2017
(86) PCT No.: PCT/US17/14558

§ 371 Date: Jul. 17, 2018

Related U.S. Application Data
(60) Provisional application No. 62/281,392, filed on Jan. 21, 2016.
(60) Provisional application No. 62/344,009, filed on Jun. 1, 2016.

(51) Int. Cl. C01B 3/00; B32B 15/01; C23C 14/16; C23C 14/18; C23C 14/34; C23C 14/24; C23C 14/58; C03C 17/09; C30B 23/02; C30B 23/08; C30B 29/10; C30B 33/02; B01J 20/02; B01J 20/32

(52) U.S. Cl. CPC C01B 3/0026; C03C 2218/32; C23C 14/165; C23C 14/185; C23C 14/34; C23C 14/24; C23C 14/16; C23C 14/5806; C03C 17/09; C30B 23/025; C30B 23/08; C30B 29/10; C30B 33/02; B01J 20/0225; B01J 20/3225; B01J 20/3204; B01J 20/3236; C03C 2217/254; C03C 2218/154; B32B 15/018

(57) ABSTRACT

Methods and apparatus for improving the loading ratio of a hydrogen gas in a transition metal are disclosed. Blocking desorption sites on the surface of a metallic structure increases the partial hydrogen/deuterium pressure when the absorption and desorption processes reach an equilibrium. The higher the number of desorption sites that are blocked, the higher the equilibrium pressure can be reached for attaining a higher hydrogen loading ratio. Moreover, since hydrogen desorption occurs at grain boundaries, reducing grain boundaries is conducive to reducing the hydrogen desorption rate. Methods and apparatus for increasing grain sizes to reduce grain boundaries are also disclosed.

### CROSS-REFERENCE TO RELATED APPLICATIONS

This application is a U.S. National Stage application of International Application No. PCT/US2017/014558, filed on Jan. 23, 2017, which claims the benefit of U.S. Provisional Application No. 62/281,392, titled Methods for Improving Loading of Hydrogen (Deuterium) Gas into Transition Metals and filed on Jan. 21, 2016, and U.S. Provisional Application No. 62/344,009, titled Methods for Improving Loading of Hydrogen (Deuterium) Gas filed on Jun. 1, 2016, the contents of which are incorporated herein by reference.

### TECHNICAL FIELD

The present invention relates to loading hydrogen/deuterium gas into a transition metal.

### BACKGROUND

Most transition metals have a capacity to absorb a large quantity of hydrogen gas and store the hydrogen gas in the metal lattices. The absorption process is a two-step process, first adsorption and then absorption. During adsorption, hydrogen molecules are adsorbed onto a surface of the transition metal. After adsorption, each of the adsorbed hydrogen molecules disassociates into two hydrogen atoms. The disassociated hydrogen atoms are then absorbed into the bulk of the metal lattices.

Several transition metals, for example, palladium, nickel, etc., have been used in a wide range of industrial applications for storing hydrogen. Under normal conditions, palladium or nickel can absorb hydrogen gas up to a certain limit. For example, palladium can attain a loading ratio of 0.7-0.8 (hydrogen atoms/metal atoms). Generally, a gas loading ratio in a piece of metal can be determined by the mass change of the metal or the pressure change in the gas. To load hydrogen beyond a ratio of 0.8 or to attain a loading ratio beyond 1.0, extraordinary conditions are needed or an exceptional long time period is required. For example, only under a pressure of 10,000 kPascal, palladium can attain a loading ratio of 0.9.

### SUMMARY

The present application discloses methods and apparatus for achieving a high loading ratio of hydrogen gas, e.g., above 0.9, without resorting to extraordinarily high pressure or temperature.

The present disclosure relates to improving loading of a hydrogen gas into a transition metal. Herein term “hydrogen gas” refers to a gas or gas mixture that comprises one or more hydrogen isotopes, e.g., protium, deuterium, or tritium.

In some embodiments, the hydrogen loading ratio that can be achieved in a piece of transition metal is improved by pre-treating the surface of the metal. Because hydrogen atoms, even after being absorbed, can escape from the metal lattice, reducing the surface area through which the absorbed hydrogen atoms can escape improves the hydrogen loading ratio. In some embodiments, the desorption area on the surface of the transition metal is reduced by deactivating the desorption sites. For example, the desorption sites can be deactivated by depositing a film on the surface of the transition metal. The transition metal with the deposited film has a reduced desorption area, and the reduced desorption area reduces the desorption rate of the hydrogen gas. The film may be metallic or semi-metallic. In one embodiment, the thickness of the film is one to five monolayers thick. A monolayer is a layer of one molecule thick.

In some embodiments, a method of improving the loading ratio of a hydrogen gas in a transition metal comprises reducing the desorption area by depositing a film on the surface of the transition metal. The film deposited on the surface of the transition metal deactivates the desorption sites on the surface.

In some embodiments, the desorption area on the surface of a transition metal can be reduced by decreasing the total grain boundaries in the transition metal. For example, the total grain boundaries in a transition metal can be decreased by increasing the average grain size in the transition metal. Therefore a further method of improving the loading ratio of a hydrogen gas in a transition metal is to increase grain sizes in the transition metal.

In one embodiment, the average grain size in a transition metal can be increased by depositing a film of the transition metal on a piece of glass. Deposition methods are used to make metallic coatings or films. Examples of deposition methods include physical vapor deposition (PVD), chemical vapor deposition (CVD), etc. In PVD, a piece of metal wire or plate is turned into vapor through a physical process, such as sputtering. In a sputter deposition process, an ion of an inert gas, such as argon, is accelerated toward a metal plate (sputtering target) with sufficient energy to dislodge metal atoms from the plate. The dislodged metal atoms or ions are accelerated under a force field to reach a substrate and are deposited onto the substrate. In one embodiment, the average grain size in the transition metal is increased by annealing the transition metal at a pre-determined pressure and a pre-determined temperature. In another embodiment, the average grain size in the transition metal is increased by evaporating an oriented metallic film of the transition metal onto an oriented substrate at a pre-determined temperature and a pre-determined pressure. The oriented grains in the metallic film preferably have an in-plane dimension greater than the thickness of the film. In one embodiment, the pre-determined pressure is between 0.1 to 1 Pascal and the pre-determined temperature is between 200° C. and 1000° C. In another embodiment, the pre-determined pressure is between 1×10⁻⁴ and 1×10⁻⁶ Pascal and the pre-determined temperature is between 150° C. and 250° C. In some embodiments, annealing is a preferred method of increasing grain sizes. Annealing causes crystal grains to grow. When crystal grains grow in size there are fewer grains and therefore smaller total grain boundaries, which results in decreased surface area available for desorption of the loaded hydrogen. In some embodiments, the methods of sputter depositing and annealing can be combined. The average grain size in the transition metal is increased due to annealing and the desorption area of the transition metal is reduced due to sputter deposition. In some embodiments, to improve the loading ratio of a hydrogen gas in a transition metal, an oriented metallic film is evaporated onto an oriented substrate at a pre-determined temperature between 150° C. and 250° C. and a pre-determined pressure between 1×10⁻⁴ to 1×10⁻⁶ Pascal. The oriented substrate may be an oriented silver substrate. The metallic film on the substrate comprises oriented grains that have an in-plane dimension greater than the thickness of the film. In one embodiment, the film may be one to five monolayers thick. In some embodiments, the transition metal may be palladium. In some embodiments, a hydrogen loading ratio of 1.0 or more can be achieved. In some embodiments, the metallic film is further annealed at a pre-determined pressure between 0.1 and 1 Pascal and a pre-determined temperature between 200° C. and 1000° C.

It is noted again that in the present disclosure, the term “hydrogen” may refer to any hydrogen isotope, protium, deuterium or tritium, or a mixture thereof.

### BRIEF DESCRIPTION OF FIGURES

FIG. 1 illustrates an exemplary metal lattice loaded with hydrogen.

FIG. 2 illustrates an exemplary hydrogen absorption and adsorption process in a metal lattice.

FIG. 3 illustrates an exemplary hydrogen desorption process in a metal lattice.

FIG. 4 illustrates different grain sizes in a metallic film.

FIG. 5 illustrates an exemplary process for improving the hydrogen loading ratio in a metal lattice.

### DETAILED DESCRIPTION

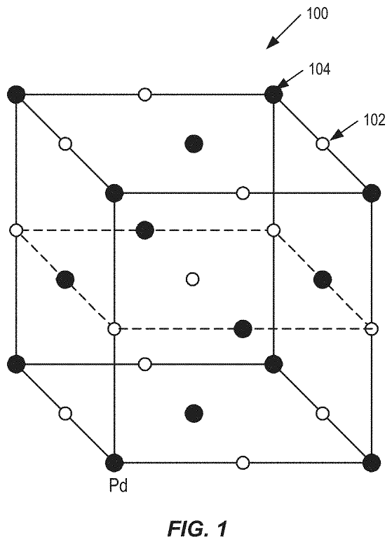

In an exemplary transition metal lattice cell 100 shown in FIG. 1, metallic atoms form a face-centered-cubic (fcc) cell. A set of dashed lines splitting the cell horizontally is included as a visual aid. The cell comprises 14 metallic atoms 104 that are located at the eight corners and the centers of each face of the cell. The fcc cell 100 is loaded with hydrogen atoms 102 that reside at octahedral interstitial sites in the lattice. In the cell structure 100, the hydrogen loading ratio is 4 hydrogen atoms to 4 metallic atoms, using the conventional counting method (⅛ of a corner atom, ¼ of an edge center atom, ½ of a face center atom, etc.). In other words, the hydrogen loading ratio in the metallic cell 100 has reached 1.0, which is very difficult to achieve under normal conditions.

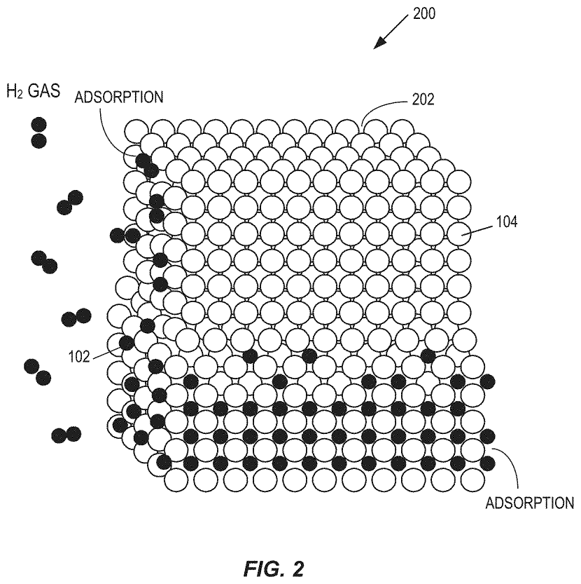

Under normal conditions, a metal or metallic structure can only attain a hydrogen loading ratio around 0.7 or 0.8. FIG. 2 illustrates a hydrogen loading process. The loading process explains why it is difficult under normal conditions for a piece of metal to achieve a hydrogen loading ration higher than 0.7 or 0.8. In FIG. 2, a metal or metal lattice 200 is partially loaded with hydrogen. On the surface 202 of the lattice 200, hydrogen molecules first dissociate into hydrogen atoms 102. The loading process of hydrogen atoms 102 onto the surface 202 is also known as adsorption and the loading process of hydrogen atoms 102 into the bulk of the lattice 200 is known as absorption. During hydrogen loading, two competing processes, absorption and desorption, take place simultaneously. In an absorption process, hydrogen atoms outside the lattice 200 diffuse into the lattice 200 and become absorbed in the lattice 200. In a desorption process, hydrogen atoms inside the lattice 200 diffuse to the surface of the lattice 200, then either remain at the surface or return to the gas phase. At the beginning of a hydrogen loading process, more hydrogen atoms diffuse into the lattice 200 than out of the lattice 200, and the absorption rate exceeds the desorption rate. Gradually, the desorption rate increases as more hydrogen atoms have been absorbed into the lattice 200. Eventually, the absorption and the desorption processes reach an equilibrium state, in which the number of hydrogen atoms 102 absorbed in the lattice 200 remains constant and the hydrogen loading ratio does not change as time goes on.

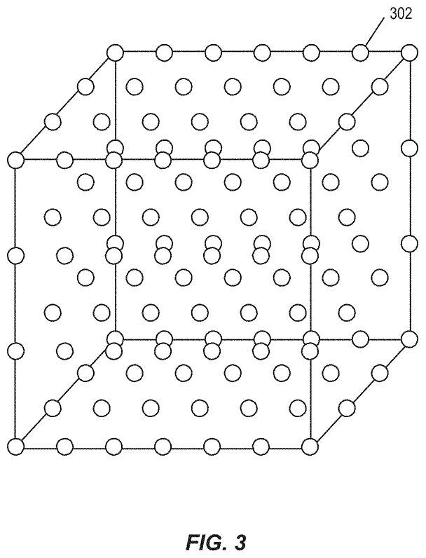

In a desorption process, hydrogen atoms escape from the lattice 200 through desorption sites on the surface 202 of the lattice 200. FIG. 3 illustrates a few desorption sites 302. The desorption sites 302 are the sites where the absorbed hydrogen atoms 102 can escape from the lattice 200 and the rate of the desorption process is proportional to the number of desorption sites 302 on the surface. Hence reduction of the number of desorption sites 302 reduces the desorption rate or slows down the desorption process. Under a slower desorption rate, the absorption rate remains higher than the desorption rate for a longer period time until the two competing processes reach an equilibrium again. During the longer period time before the equilibrium is reached, more hydrogen atoms are absorbed, thus improving the hydrogen loading ratio.

In many industrial applications, it is desirable to achieve a high hydrogen loading ratio, for example, higher than 1.0. Studies have shown that high or ultra-high pressure, e.g., higher than 10,000 kPascal, is conducive to attaining a hydrogen loading ratio of 1.2. Studies have also shown that a wide variety of temperatures and pressure cycles can help achieve high hydrogen loading ratios. Other techniques for achieving a hydrogen loading ratio in a metallic structure include electrolytic co-deposition, ion implantation, and use of nanoparticles. Several investigations further suggest that strong magnetic fields, high voltage, high electrolytic currents, etc., can be used to achieve a hydrogen loading ratio above 1.0.

The present disclosure teaches advantageous methods and apparatus for increasing hydrogen loading ratios in a metallic structure without requiring a hydrogen pressure beyond 200 kPa. In the present disclosure, metallic structure refers to a metal or metallic or alloy lattice.

Suitable metals or metallic structures are elected from a group of transition metals comprising palladium, iridium, nickel, platinum, copper, silver, gold, zinc, titanium, zirconium, hafnium, chromium, vanadium, niobium, tantalum, molybdenum, tungsten, iron, ruthenium, rhodium, aluminum, indium, tin, lead, and mixtures thereof. In some embodiments, palladium is preferred. In some embodiments, a hydrogen loading ratio of 1.0 or more is achieved. In some embodiments, a hydrogen loading ratio between 1.0 and 1.8 is achieved.

In some embodiments, a portion of the hydrogen desorption sites on the surface of a metallic structure, e.g., a palladium lattice, are deactivated by a metallic or semi-metallic film deposited on the surface of the metallic structure. The film may be created using one or more of the following elements: titanium (Ti), zirconium (Zr), hafnium (Hf), vanadium (V), niobium (Nb), tantalum (Ta), chromium (Cr), molybdenum (Mo), tungsten (Ta), iron (Fe), aluminum (Al), gallium (Ga), indium (In), silicon (Si), germanium (Ge), and tin (Sn). In some embodiments, the thickness of the film ranges from one to five monolayers thick and the film is deposited by sputtering a single-metal target, or multiple targets of different metals, or an alloy target. The deposition conditions for creating a thin film of only one to five monolayers are calibrated using cross-sectional transmission electron microscopy of previously deposited films. In some embodiments, the film can cover 10 to 99% of the surface area. In one embodiment, a film of a thickness of one to five monolayers covers more than half of the surface area. In another embodiment, the film covers less than half of the surface area. Calculations show that blocking 10% of the desorption sites results in a factor of 1.2 increase in hydrogen (deuterium) partial pressure at the unblocked sites, while blocking 99% of the desorption sites yields a factor of 10,000 increase in hydrogen (deuterium) partial pressure.

In some embodiments, the film is deposited by sputtering of one metal target or multiple metal targets. In some embodiments, the film is deposited by sputtering of a single-metal target, multiple targets of different metals or an alloy target. Sputtering yield of a metal target is a function of the sputtering deposition conditions. Sputter yield is defined as the number of atoms released from a target when impinged by a sputtering ion. Sputter yield of a particular metal is dependent on the requisite energy of the sputtering ion. For example, an argon ion with an energy of 300 electron volts (eV) is required to sputter one atom of nickel. Comparatively, a xenon ion with an energy of 400 eV is required to sputter one atom of nickel.

Desorption sites are where absorbed hydrogen atoms escape the lattice 200. Some desorption sites 302 are located on the surface 202 of the lattice 200, as shown in FIG. 3. Some desorption sites are located on grain boundaries (not shown in FIG. 3) of the lattice 200. A grain refers to a portion of the metallic structure in which the crystal arrangement is uninterrupted. Grain boundaries are interruptions in the continuous crystal structure and essentially behave like internal surfaces in the metallic structure. Reducing grain boundaries in the metallic structure reduces the total surface area. As a result, the number of desorption sites is reduced, thus slowing down the desorption rate.

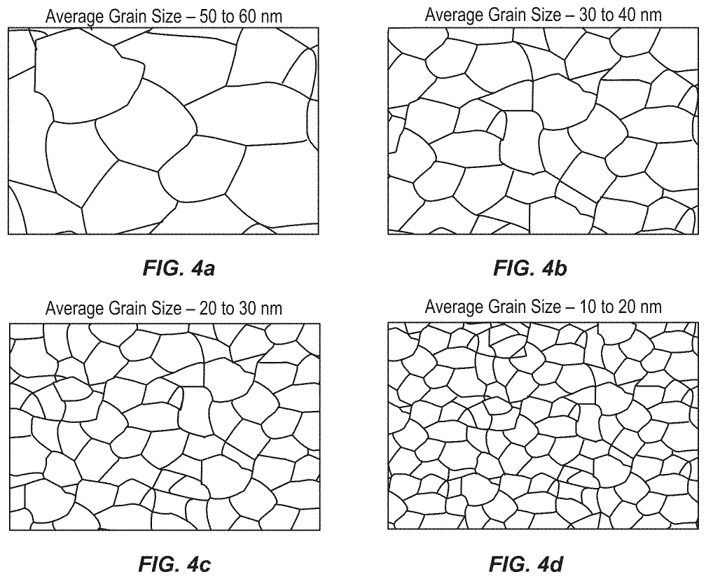

In some embodiments, reduction of grain boundaries is achieved by increasing grain sizes. FIGS. 4a-4d illustrate four exemplary metallic structures that are prepared, e.g., annealed, under different conditions, e.g., temperature and pressure. The average grain size in each of the four exemplary metallic structures is different due to the different annealing conditions. For example, in FIG. 4a, the average grain size in the metallic structure is the largest, ranging approximately from 50 to 60 nm. In FIG. 4b, the average grain size ranges from 30 to 40 nm. In FIG. 4c and FIG. 4d, the metallic structures are fragmented to a large extent and the grain sizes are smaller than those in FIG. 4a or FIG. 4b. The average grain size in FIG. 4c falls in the range of 20 to 30 nm and the average grain size in FIG. 4d falls in the range of 20-10 nm. As shown in FIGS. 4a-4d, the larger the grain sizes are, the smaller the total area of the grain boundaries becomes. Therefore, increasing the grain sizes can reduce the grain boundaries, which in turn can reduce the hydrogen desorption rate.

The following are a few embodiments that demonstrate the process and/or the system that can be used to increase the average grain size in a metallic structure. In some of the embodiments, a specific metal or material, e.g., palladium or glass, is used as an example for illustration purposes. It is noted that the process and the system disclosed herein can be adapted to treat or prepare other metals or alloys or any materials of similar properties.

In one embodiment, a transition metal sample, e.g., palladium, is annealed under vacuum at a pressure of 0.1 to 0.001 Pascal and a temperature of 200 to 1000° C. for 10 to 60 minutes to induce grain growth. Increasing the average grain size of the metal sample decreases the total grain boundaries in the sample, which decreases the potential area for hydrogen desorption.

In one embodiment, annealing is used to increase grain sizes in a palladium sample. The sample is annealed in an inert gas under a pressure of nominally 100 kilopascals at a temperature that ranges from 200° C. to 1000° C. The annealing process lasts for about 10 to 60 minutes to induce grain growth. The inert gas (sputtering gas) may be argon or any gas such as nitrogen, carbon dioxide or another noble gas that does not form a compound or diffuse into the palladium sample under the annealing conditions. In some embodiments, argon is preferred.

As described above, the total grain boundaries can be reduced by increasing the average grain size in a metallic structure. In some embodiments, improved sputter deposition processes are employed to create a metallic film in which the average grain size in the film is as large as the thickness of the film. In one embodiment, a 5 to 200 nm palladium film is sputter deposited on a piece of glass in an inert gas at 0.1 to 1 Pascal total pressure at a power of 100 to 1000 W. When the dimensions of a grain in the palladium film are approaching, e.g., either becoming larger than or equal to, the thickness of the film, the average hydrogen atom diffusion distance is shorter through the thickness of the film than across a grain boundary, thus minimizing desorption via grain boundaries.

In another embodiment, a 5 to 200 nm thick palladium film is sputter deposited on a piece of quartz glass at 0.1 to 1 Pascal total pressure in an inert gas at a power of 100 to 1000 W. The film is annealed under an appropriate annealing condition until the grain size is greater than the thickness of the film. For example, the palladium film is annealed in the presence of an inert gas at nominally 100 kilopascals pressure and at a temperature between 200° C. and 1000° C. The annealing process lasts for about 10 to 60 minutes. For another example, the palladium film is annealed under vacuum at a pressure of 0.1 to 1.1 Pa at a temperature that ranges from 200° C. to 1000 ° C. for 10 to 60 minutes to induce grain growth.

In some embodiments, the substrate used in sputter deposition is an oriented silver substrate.

In some embodiments, a 25 to 50 nm (100)-oriented palladium film is evaporated onto a (100)-oriented silver (Ag) substrate at a pressure of 1×10⁻⁴ to 1×10⁻⁶ Pa and 150° C. to 250° C. substrate temperature resulting in a (100)-oriented grains which have an in-plane dimension greater than 50 nm. It is noted that (100)-oriented refers to the plane of Miller index 100, i.e., a plane that cuts the x-axis but runs parallel to both the y and z axes. These are examples of two films where all grains are of the same orientation. When oriented films are used, the grains will more easily coalesce to form larger grains than would grains of random orientation. Any film in which all grains have approximately the same orientation has this advantageous behavior and can be used in the methods and apparatus disclosed herein. No particular plane or range of planes is more suitable or preferred.

In some embodiments, a 25 to 50 nm (111)-oriented palladium film is evaporated onto a (111)-oriented Ag substrate at 1×10⁻⁴ to 1×10⁻⁶ Pascal and 150° C. to 250° C. temperature resulting in a (111)-oriented grains which have an in-plane dimension greater than 50 nm. It is noted that (111)-oriented refers to the 111 plane that cuts through a diagonal line of a cell face and an opposing vertex. These are examples of two films in which substantially all grains will be of approximately the same orientation.

In some embodiments described above, the hydrogen loading ratio of 1.0 or more can be achieved. In some embodiments, the hydrogen loading ratio is preferably from 1.0 to 1.8.

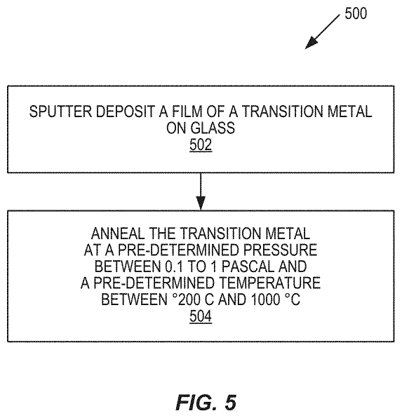

FIG. 5 is a flow chart depicting an exemplary process for improving hydrogen loading in a metallic material. The exemplary process illustrated in FIG. 5 is one embodiment of the pre-treatment that can be employed to reduce the desorption area of the metallic material. Reduction of the desorption area can be achieved by either reducing the number of desorption sites on the surface of the metallic material or increasing the average grain size in the metallic material. FIG. 5 illustrates an exemplary method for increasing the average grain size in the metallic material. In the exemplary method 500, a film of a transition metal is first sputter deposited on a piece of glass (step 502). The film is annealed at a pre-determined pressure between 0.1 to 1 Pascal and a pre-determined temperature between 200° C. and 1000° C.

A further method of improving the loading ratio of a hydrogen gas in a transition metal comprises (i) providing a transition metal as substrate, (ii) providing a sputtering target, (iii) providing a sputtering gas, (iv) sputtering the sputtering target with sputtering gas to dislodging metal atoms or ions from the sputtering target, and (v) depositing dislodged metal atoms or ions on the substrate.

The present invention may be carried out in other specific ways than those herein set forth without departing from the scope and essential characteristics of the invention. The present embodiments are, therefore, to be considered in all respects as illustrative and not restrictive, and all changes coming within the meaning and equivalency range of the appended claims are intended to be embraced therein.

What is claimed is:

1. A method of improving the loading ratio of a hydrogen gas in a transition metal, comprising:
depositing a film on a surface of the transition metal;
deactivating, through the deposited film, desorption sites on the surface of the transition metal; wherein the desorption area of the transition metal is reduced due to the deactivated desorption sites;
wherein the reduced desorption area reduces a desorption rate of the hydrogen gas and improves the loading ratio of the hydrogen gas.

2. The method of claim 1, wherein the film is metallic.

3. The method of claim 1, wherein the film is semi-metallic.

4. The method of any of the preceding claims, wherein the film is one to five monolayers thick.

5. The method of claim 1, wherein the film comprises one or more of the following elements: titanium, zirconium, hafnium, vanadium, niobium, tantalum, chromium, molybdenum, tungsten, iron, aluminum, gallium, indium, silicon, germanium, and tin.

6. The method of claim 1, wherein the transition metal is palladium, iridium, nickel, platinum, copper, silver, gold, zinc, titanium, zirconium, hafnium, chromium, vanadium, niobium, tantalum, molybdenum, tungsten, iron, ruthenium, rhodium, aluminum, indium, tin, lead, or mixtures thereof, preferably palladium.

7. The method of claim 1, wherein the improved hydrogen loading ratio is 0.9 or more.

8. A method of improving the loading ratio of a hydrogen gas in a transition metal, comprising:
sputter-depositing a film of the transition metal on a substrate; and annealing the transition metal at a pre-determined pressure between 0.1 to 1.0 Pascal and a pre-determined temperature between 200° C. and 1000° C.,
wherein an average grain size in the transition metal is increased and a desorption area of the transition metal is reduced; and wherein the loading ratio of a hydrogen gas in the transition metal is improved.

9. The method of claim 8, wherein the transition metal is palladium.

10. The method of claim 8, wherein the substrate is an oriented silver substrate.

11. The method of claim 8, wherein the substrate is glass.

12. The method of claim 8, wherein the hydrogen loading ratio is 0.9 or more.

13. The method of claim 8, wherein the film is one to five monolayers thick.

14. A method of improving the loading ratio of a hydrogen gas in a transition metal, comprising:
evaporating the transition metal;
depositing the evaporated transition metal to form an oriented metallic film of the transition metal onto an oriented substrate, wherein the deposition of the oriented metallic film is performed at a pre-determined temperature between 150° C. and 250° C. and a pre-determined pressure between 1×10⁻⁴ to 1×10⁻⁶ Pascal;
wherein the metallic film on the substrate comprises oriented grains that have an in-plane dimension greater than the thickness of the film.

15. The method of claim 14, wherein the transition metal is palladium.

16. The method of claim 14, wherein the substrate is an oriented silver substrate.

17. The method of claim 14, wherein the hydrogen loading ratio is 1.0 or more.

18. The method of claim 14, wherein the film is one to five monolayers thick.

19. The method of claim 14, further comprising annealing the transition metal at a pre-determined pressure between 0.1 to 1 Pascal and a pre-determined temperature between 200° C. and 1000° C.
